(19) United States
(12) Patent Application Publication
(10) Pub. No.: US 2005/0035441 A1
(43) Pub. Date: Feb. 17, 2005

(54) Integrated circuit stack with partially etched lead frames

(76) Inventors: Kwanghak Lee, Fremont, CA (US); Erin James Jesswein, Fremont, CA (US)

Correspondence Address: Eugene Oak;Ph.D.,J.D., Patent Attorney, 610 S. Van Ness Ave., Los Angeles, CA, 90005, US

(21) Appl. No.: 10/640,952

(22) Filed: Aug. 15, 2003

(51) Int. Cl. H01L 23/02

(52) U.S. Cl. 257/686

(57) ABSTRACT

A novel multi chip module having a high accuracy of stacking and self alignment of integrated circuits (ICs) during the stacking process is provided by utilizing partially half etched lead frames and package guide lead frames. Heat dissipation is increased by a plurality of etched lead portions directly connected to the “Bottom IC” body and adhered to the “Top IC” body with thermally conductive glue. Applying the partially etched lead frame of this invention decreases number of steps in the IC stacking process. The lead frame used in this invention is made of the same material used in a genuine IC, providing optimal signal quality by minimizing any signal reflection.

### BACKGROUND OF THE INVENTION

As the need for high density IC boards increases, many kinds of stacking methods for connecting ICs are being developed. The Multi Chip Module (MCM) is one of the methods used to stack a group of ICs on one board. MCMs are categorized into following three types according to the substrates used; 1) MCM-L, having a resin-based printed circuit board, 2) MCM-C, using a ceramic multi-layer substrate prepared by printing interconnections respectively on ceramic green sheets, laminating these green sheets, and sintering the laminated green sheets, and 3) MCM-D, having a thin film multi-layer substrate. These MCMs are used to connect bare chips on a board using wires. Another method is to pile single ICs, having lead frames, vertically. Regardless of the connecting routes, the lead of one IC is connected to the lead of another IC by means of soldering. However, it is very difficult to put the exact amount of solder at the exact position on the shoulder area of the leads of a “bottom” IC. Many companies deform the leads of the original IC into a “J” type or “S” type to increase the shoulder area. Nevertheless, such deformation of IC leads may cause a change in the characteristic function of the original IC. It is the intent of this invention to provide a novel structure for increasing the accuracy of soldering without deforming the leads of the original ICs.

1. Field of the Invention

This invention relates to the structure of a multi chip module having increased soldering accuracy for ICs with one lead frame, but half etched in areas where bottom ICs are seated, and with an IC body guide bar.

2. Description of the Prior Art

U.S. Pat. Nos. 6,465,279 and 6,340,840 to Oshawa et al. illustrate a selectively etched lead frame to form a contour of lead frame, forming a guide hole, etc. The etching is used to remove the additional layer on the surface of a metal base member. In other words, they coat the lead frame and etch the coating layer. The other method of etching is to remove the metal base opposite the coated layer perfectly to expose planes opposed to the insulating film and to perfectly form the contours of the outer leads. Not half thickness etching. In this step, the metal base is totally removed and the etching stops at the etching stopper layer, which is developed on the other side of the metal base opposite the side where the etching proceeds.

U.S. Pat. No. 6,443,355 to Tsurusaki illustrates a soldering method and apparatus in which the substrate board is inverted for soldering the other side of the circuit board. However, this art is not developed for the micro-scale soldering leads to leads in a multi chip packing procedure.

U.S. Pat. No. 6,313,998 to Kledzik, et al. illustrates a circuit board assembly having integrated circuit packages vertically arranged. A package carrier having a plurality of carrier leads and a secondary mounting pad array on an upper surface thereof, covers the first package. U.S. Pat. No. 6,084,293 to Ohuchi illustrates a stack type semiconductor device, wherein the front ends of leads provided at two sides of a first semiconductor device are bent inward to hold a second semiconductor device stacked at the rear surface of the first semiconductor device.

U.S. Pat. No. 6,028,352 to Eide illustrates an IC stack utilizing secondary lead frames. Each layer is formed by mechanically and electrically joining an IC-containing TSOP with an external lead frame. Each lead frame contains conductors which are disposed to connect with TSOP leads, transpose signals to other locations on the periphery of the TSOP, and/or connect with other layers in the stack. U.S. Pat. No. 5,978,227 to Burns illustrates an integrated circuit package having an externally mounted lead frame having bifurcated distal lead ends.

U.S. Pat. No. 5,960,539 to Burns describe a method of making a high-density IC module having complex electrical interconnection. U.S. Pat. No. 5,514,907 to Moshayedi illustrates a multi-chip memory module comprising multiple standard, surface-mount-type memory chips stacked on top of each other, and a pair of printed circuit boards mounted on opposite sides of the memory chips to electrically interconnect the memory chips.

All of the prior art illustrate soldering leads of an IC to other ICs. However, none of the prior art illustrates a soldering method utilizing half etched lead frames to increase the accuracy of soldering IC leads to an additional lead frame and also increase heat dissipation.

### SUMMARY OF THE INVENTION

A novel multi chip module having a high accuracy of stacking and self alignment of integrated circuits (ICs) during the stacking process is provided by utilizing half etched (actually forming a groove by two half etched lead frames) lead frames and an IC body guide bar. Arrays of half etched lead frames are mounted on a bottom tool guided by tooling pins. Solder pastes are printed on un-etched portions of arrays of lead frames (solder pads for bottom IC). Bottom ICs are mounted on the etched portions of the lead frames facing downward and positioning the leads of the bottom IC on the solder paste.

After an inspection for proper placement, the module is passed through a re-flow oven. The bottom IC assemblies are flipped upside down and placed on top of the tools. Solder paste is applied to the un-etched portions of the first arrays of lead frames and solder pads attached to the top IC. Thermally conductive epoxy resin is dispensed on the extended leads of half etched portions of the arrays of lead frames. The top ICs are placed on the assemblies of the bottom ICs locating the tip end of the top IC leads on the solder paste.

After another inspection for proper placement, the module is again passed through the re-flow oven. A final visual inspection is performed and necessary final adjustments are made.

The lead frame is cut along a line marked using a laser trimming machine. The groove formed between the non etched (solder pads), the half etched areas and the IC body guide bar allows the “Bottom IC” to be accurately positioned at the center of the additional frame. After singulating from the array, each solder pad is securely held between the top and bottom IC body by means of epoxy glue. This prevents them from moving or dropping out from between the two IC bodies when applying hot air for re-flow or wave soldering.

### BRIEF DESCRIPTION OF THE DRAWINGS

FIG. 1 is an exploded isomeric view of the multi-chip module of this invention utilizing half etched additional lead frame.

FIG. 2 is a cross sectional view of the multi-chip module of this invention at the line b-b′, showing half etched pattern area, in FIG. 1.

FIG. 3 is a cross sectional view of the multi-chip module of this invention at the line a-a′, showing half etched open pin area, in FIG. 1.

FIG. 4 is a structure drawing of half etched lead frame used for this invention.

FIG. 5 is a structure drawing of a strip of half etched lead frame used for this invention.

FIG. 6 is a schematic drawing of a half etched lead frame mounted on bottom tool and solder paste on un-etched part of the lead frame.

FIG. 7 is a schematic drawing of the “bottom IC” mounted upside down positioned on the half etched lead frame on bottom tool.

FIG. 8 is a schematic drawing of the “bottom IC” and soldered frames mounted up right position on the top tool and the positions of additional soldering and glue dispersion and “top IC”.

FIG. 9 is a schematic drawing of the “bottom IC” mounted on a top tool.

FIG. 10 is a schematic drawing of a half etched frame mounted on a upper face of a “bottom IC” guided by positioning pins FIG. 11 is a schematic drawing of Epoxy resin dispensed on an upper face of a “bottom IC” at the tip ends of the half etched lead frames.

FIG. 12 is a schematic drawing of “top IC” mounted on an upper face of a “bottom IC” and the area exposed to wave solder.

### DETAILED DESCRIPTION OF THE PREFERRED EMBODIMENTS

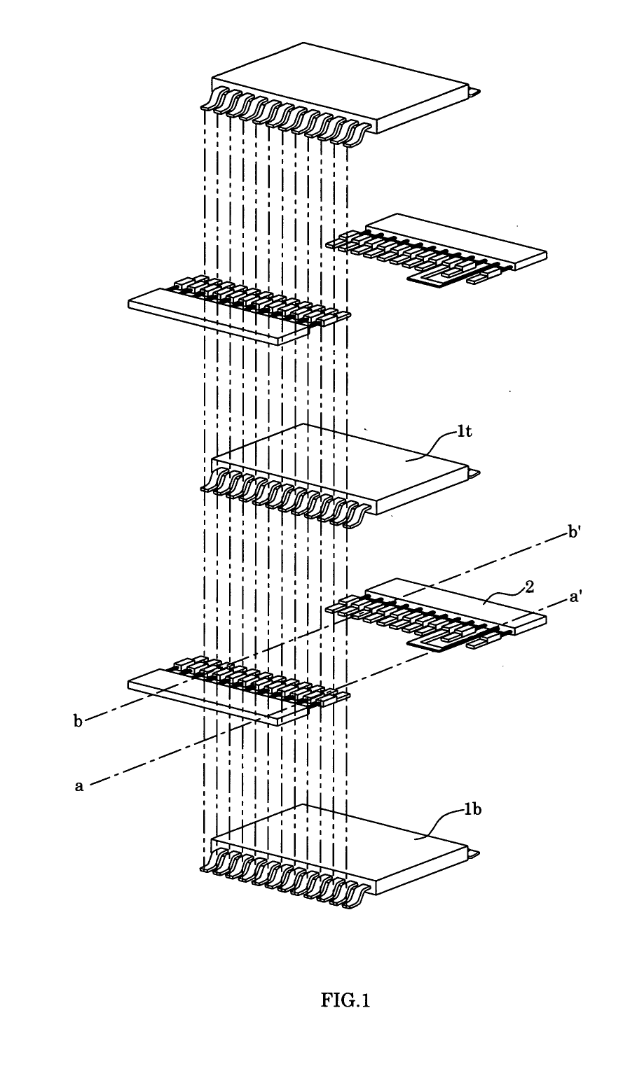

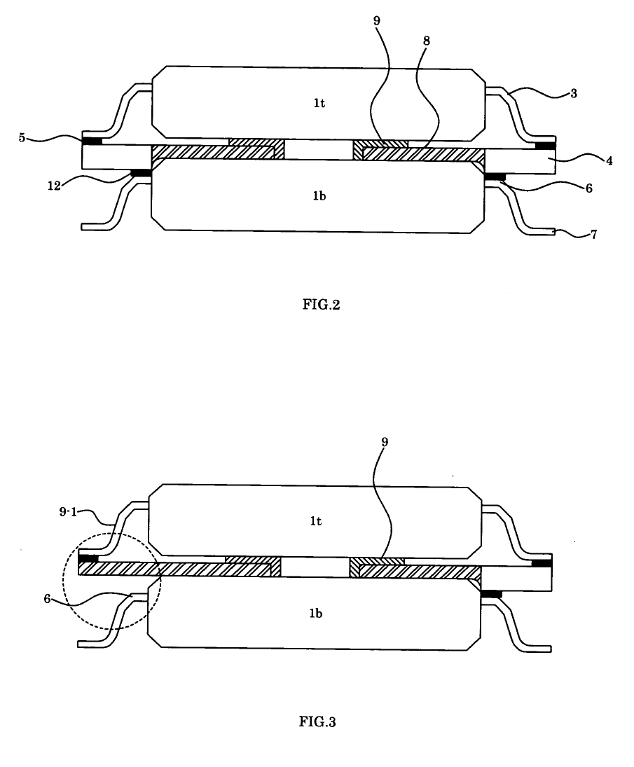

FIG. 1 is an exploded isomeric view of the multi-chip module of this invention. Two integrated circuits “top IC” (1t) and “bottom IC” (1b) are connected by un-etched portion of a half etched lead frame (2). Referring to FIG. 2, a cross sectional view of the half etched area of the multi-chip module at the line b-b′, leads (3) of the “top IC” (1t) are soldered to the pads (4) of the half etched lead frame (2) by means of solder paste (5). The pads (4) of the lead frame (2) are again soldered on to the shoulder (6) of the leads (7) of the “bottom IC” (1b). The half etched part (8) of the lead frame (2) directly contacts the “bottom IC” body and adheres to the “top IC” (1t) via thermal conductive glue (9). Heat generated in each of the ICs (1b and 1t) is conducted to the leads (3 and 7) of the ICs through the connected pads and radiated into the air.

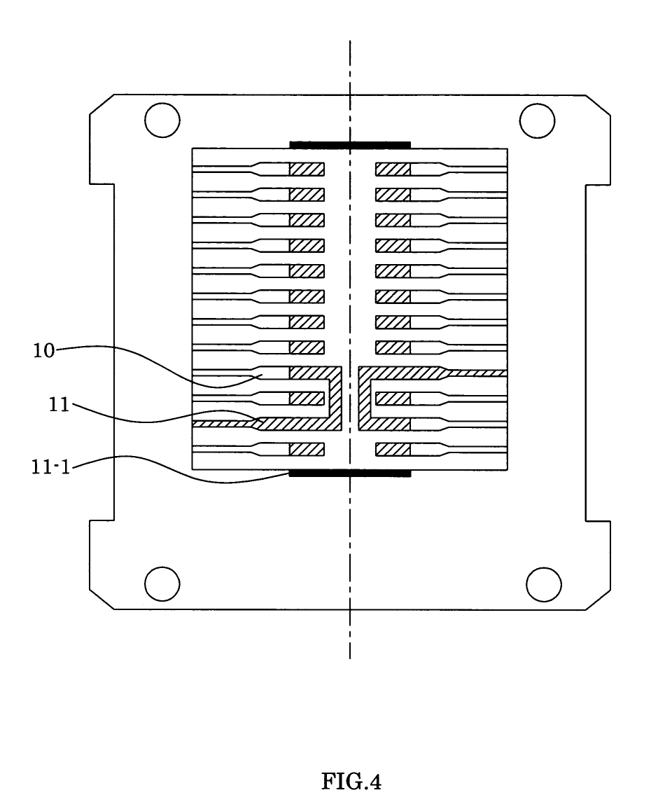

FIG. 3 is a cross sectional view of the multi-chip module of this invention at the line a-a′, showing half etched open pin area, in FIG. 1. Some of the pad is not connected to the shoulder (6) of the lead (7) of the “bottom IC” (1b). This un-connected pin is called a “chip selector pin”. This chip select pin is not tied with combination IC pin to be controlled each ICs (“top IC” and “bottom IC”) separately. Instead “chip selector pin of Top IC (9-1) in FIG. 3 which is pin 11 in FIG. 4 receives the control signal through pin (10) in FIG. 4 Pin 10 is non connection pin with chip inside. FIG. 4 is a structural drawing of the half etched lead frame (2) used for this invention. IC guide bars (11-1) at upper- and lower-ends of the inner boundaries of the lead frame (2) limits a “bottom IC” to place on the half etched portion (8) of the lead frame (2) with a displacement allowance of +0.05 mm in vertical direction. FIG. 5 is a structure drawing of a strip of the lead frame (2). A strip having eight lead frames on it is used in the actual process. The role of this half etched lead frame (2) is to receive the “bottom IC” (1b) at the exact center of the lead frame (2) and allow the shoulder of the “bottom IC” to be positioned at the exact point of the solder (12).

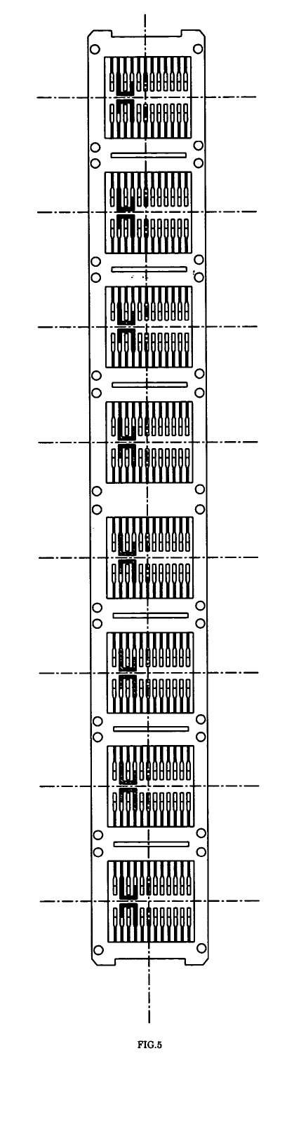

FIG. 6 is a schematic drawing of a half etched lead frame (2) mounted on a bottom tool (15) and solder pasted (12) on un-etched part (14) of the lead frame.

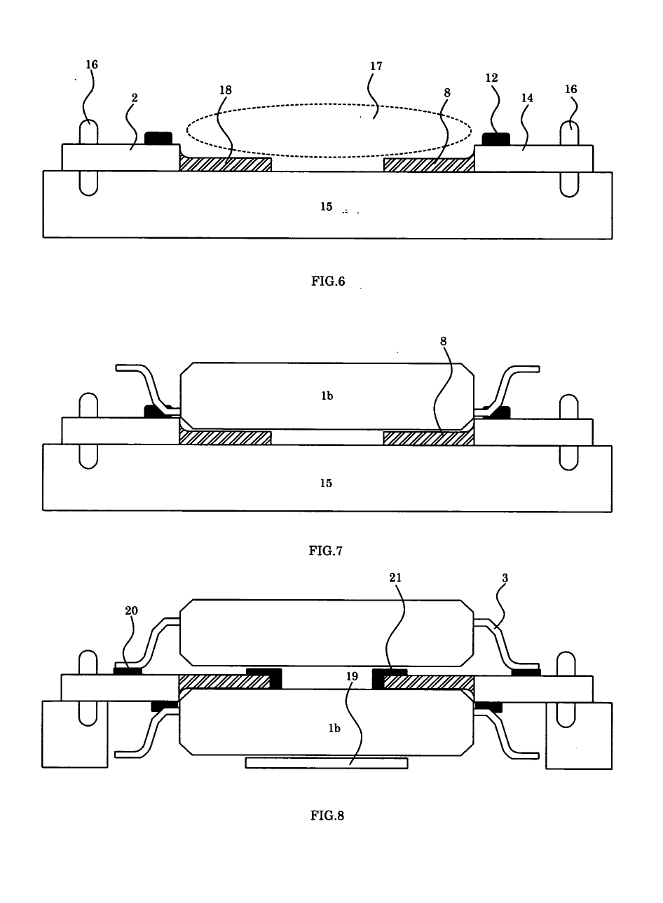

FIG. 7 is a schematic drawing of the “bottom IC” mounted upside down positioned on the half etched lead frame on bottom tool. When the materials are ready, the lead frame (2) is placed on the bottom tool (15) using tooling pins (16). Solder (12) is applied to the un-etched part (14) of the lead frame (2) using an auto printer with stencil, not shown in this invention. The “bottom IC” is then placed in the pocket (17), shown in FIG. 6, formed by the etched part (18) of the lead frame (2) guided with tooling pins (16) in each lead.

The “bottom IC” assembly is flipped over and placed on a top tool (19) guided with tooling pins (16). FIG. 8 is a schematic drawing of the “bottom IC” (1b) and soldered frames mounted upright on the top tool (19) and the positions of additional solder (20) and glue (21) dispersions. Solder (20) is applied to the un-etched part of the lead frame (2) using an auto printer with stencil. Thermal conductive glue (21) is dispensed on the inner tip of the etched part of the lead frame (2).

The “top IC” (1t) is placed on the lead frame (2) by a machine matching each lead (3) of the “top IC” (1t) to corresponding pads on the lead frame (2). The final state is shown in FIG. 2 and FIG. 3. After exposing the assembled ICs to a programmed heat treatment, visual inspection and repair are performed. This is followed by chemical cleaning and laser trimming to singulate each stack from strip.

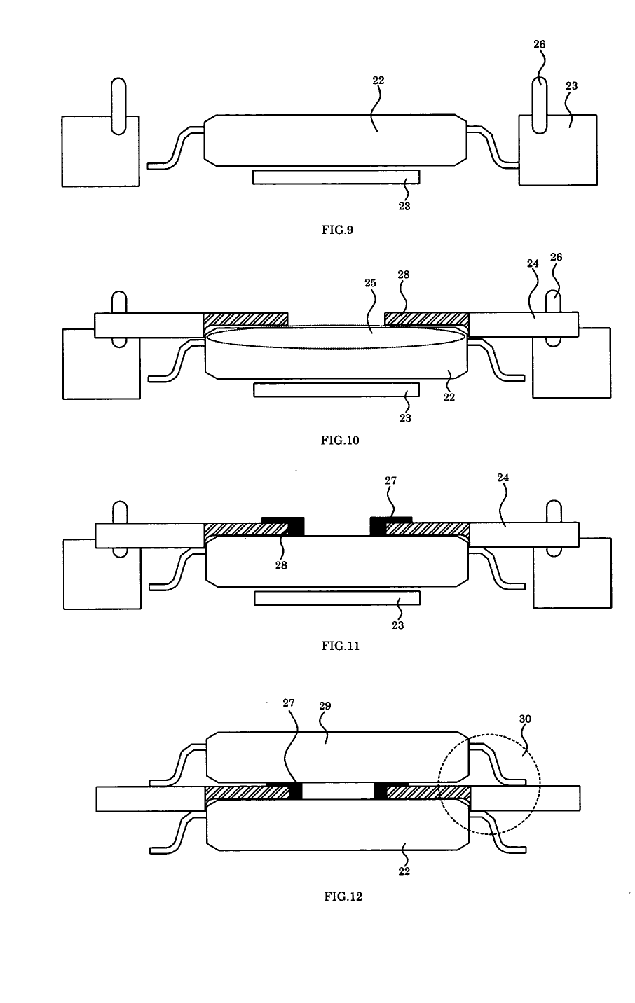

FIGS. 9 to 12 illustrate another embodiment of the present invention. FIG. 9 is a schematic drawing of a “bottom IC” (22) mounted on a top tool (23). A lead frame with half etched pin (24) is placed on a “bottom IC” (22) with a groove (25) formed by half etched areas facing the “bottom IC” (22) and positioned by guiding pins (26) as shown in FIG. 10. Thermally conductive epoxy resin (27) is dispensed on the tip ends (28) of the half etched lead frame (24) as shown in FIG. 11. A “top IC” (29) is placed on the “bottom IC” (22), with the epoxy resin (27) dispensed on the tip ends (28) of the half etched lead frame (24), positioned at the center of the bottom of the “top IC” (29) as shown in FIG. 12. The singluated “top IC” (29) and “bottom IC” (22) assembly is exposed to heat to harden the epoxy bonding. The marked area (30) is then exposed to wave solder, not shown in this invention.

The best mode of this invention is to use a copper lead frame having a 0.3 mm thickness for unetched portions and 0.15 mm thickness for etched portions.

1. A multi chip module having accuracy of soldering integrated circuits (ICs) of ±0.05 mm, utilizing a half etched copper lead frame having a 0.3 mm thickness in unetched zones of solder pads and 0.15 mm thickness in etched zones, and produced by a special method consisting of seven key steps, namely; 1) mounting a half etched lead frame on a bottom tool positioned by tooling pins, 2) applying solder on the solder pad, the un etched portion of the half etched lead frame, 3) mounting a “bottom IC”, with the shoulder of the leads of the “bottom IC” contacting the paste, in the groove which is formed by the two etched portion of the half etched lead frame, 4) turning over the combination of the “bottom IC” and half etched lead frame in step 3) and mounting the combination on a top tool positioned by another tooling pins, 5) dispensing a thermally conductive epoxy glue on the etched tip of the half etched lead frame and printing solder on the solder pad, 6) placing a “top IC” on the combination of the “bottom IC” and half etched lead frame with the legs of the leads of the “top IC” adhered to the glue on the solder pad, 7) heat treating for solder and epoxy glue.

2. A multi chip module having accuracy of soldering integrated circuits (ICs) of ±0.05 mm, in claim 1, utilizing a groove formed by space between two half etched portion of an additional lead and utilizing a IC body guide bar designed as the same length of IC body.

3. A multi chip module having accuracy of soldering integrated circuits (ICs) of ±0.05 mm, in claim 1, utilizing half etched portion between IC bodies with epoxy glue for preventing moving out of the pads when applying hot air for rework.

4. The half etched lead frame, in claim 1, has one pin, which is etched up to the solder pad zone for no connection with combinated Ic's lead.

5. A multi chip module having accuracy of the soldering the integrated circuits (ICs) of ±0.05 mm, utilizing a half etched copper lead frame, which has 0.3 mm thickness in un-etched zone of solder pad and 0.15 mm thickness in etched zone, and produced by utilizing a turning over method, which consists of 5 key steps of; 1) mounting a “bottom IC” on a top tool positioned by tooling pins, 2) placing a half etched lead frame guided by positioning pins, 3) dispensing a thermally conductive epoxy glue on the etched tip of the half etched lead frame, 4) placing a “top IC” on the half etched lead frame with the legs of the leads of the “top IC” place on the solder pad, 5) exposurering the soldering pad and legs of the leads of the “Top IC” to a wave solder.

6. A multi chip module having accuracy of soldering integrated circuits (ICs) of ±0.05 mm, in claim 5, utilizing a groove formed by space between two half etched portion of an additional lead.

7. The half etched lead frame, in claim 5, has one pin, which is etched up to the solder pad zone for no connection with combinated IC's lead.
